(19) United States
(12) Patent Application Publication
(10) Pub. No.: US 2026/0006981 A1
(43) Pub. Date: Jan. 1, 2026

(54) LIGHT-EMITTING ELEMENT, DISPLAY DEVICE, AND METHOD FOR MANUFACTURING LIGHT-EMITTING ELEMENT

(71) Applicant: Sharp Display Technology Corporation, Kameyama City, Mie (JP)

(72) Inventors: HIROFUMI YOSHIKAWA, Sakai City, Osaka (JP); YASUSHI ASAOKA, Sakai City, Osaka (JP); Yuma YAGUCHI, Sakai City, Osaka (JP)

(21) Appl. No.: 18/880,624

(22) PCT Filed: Aug. 2, 2022
(86) PCT No.: PCT/JP2022/029583

§ 371 Date: Jan. 2, 2025

(51) Int. Cl. H10K 50/115; H10K 50/15; H10K 50/16; H10K 50/17; H10K 71/12; H10K 85/60; H10K 102/00

(52) U.S. Cl. CPC H10K 50/115; H10K 71/12; H10K 85/60; H10K 50/15; H10K 50/16; H10K 50/17; H10K 50/171; H10K 2102/351

(57) ABSTRACT

A light-emitting element includes a light-emitting layer located between a first electrode and a second electrode, the light-emitting layer including quantum dots and including fluorine, a first function layer located between the first electrode and the light-emitting layer, a second function layer located between the second electrode and the light-emitting layer, and a fluorine-containing film located between the first function layer and the second function layer.

### TECHNICAL FIELD

The disclosure relates to a light-emitting element and the like.

### BACKGROUND ART

PTL 1 discloses a quantum dot composition containing a quantum dot whose surface is modified with a ligand containing fluorine and a fluororesin.

### CITATION LIST

### Patent Literature

PTL 1: WO 2020/241112 A1

### SUMMARY

### Technical Problem

There is an issue in that a light-emitting element using a known quantum dot composition is low in luminous efficiency.

### Solution to Problem

A light-emitting element according to an aspect of the disclosure includes a first electrode and a second electrode, a light-emitting layer located between the first electrode and the second electrode, the light-emitting layer including quantum dots and including fluorine, a first function layer located between the first electrode and the light-emitting layer, a second function layer located between the second electrode and the light-emitting layer, and a fluorine-containing film located between the first function layer and the second function layer.

A method for manufacturing a light-emitting element according to an aspect of the disclosure includes forming a first function layer; forming a fluorine-containing film on the first function layer, and applying a solution including a compound including fluorine and quantum dots onto the fluorine-containing film.

### Advantageous Effects of Disclosure

According to an aspect of the disclosure, it is possible to improve luminous efficiency and reliability of a light-emitting element.

### BRIEF DESCRIPTION OF DRAWINGS

FIG. 1 is a schematic view illustrating a configuration of a light-emitting element according to a first embodiment.

FIG. 2 is a cross-sectional view illustrating a configuration example of the light-emitting element.

FIG. 3 is a cross-sectional view illustrating a configuration example of a display device including the light-emitting element according to the first embodiment.

FIG. 4 is a flowchart illustrating an example of a method for manufacturing the light-emitting element according to the first embodiment.

FIG. 5 is a cross-sectional view illustrating a configuration and a carrier path of a comparative example.

FIG. 6 is a cross-sectional view illustrating a carrier path of the light-emitting element according to the first embodiment.

FIG. 7 is a cross-sectional view of a light-emitting element according to a second embodiment.

FIG. 8 is a cross-sectional view of a light-emitting element according to a modified example of the second embodiment.

FIG. 9 is a flowchart illustrating an example of a method for manufacturing a light-emitting element according to a third embodiment.

FIG. 10 is a cross-sectional view illustrating an example of the method for manufacturing the light-emitting element according to the third embodiment.

### DESCRIPTION OF EMBODIMENTS

### First Embodiment

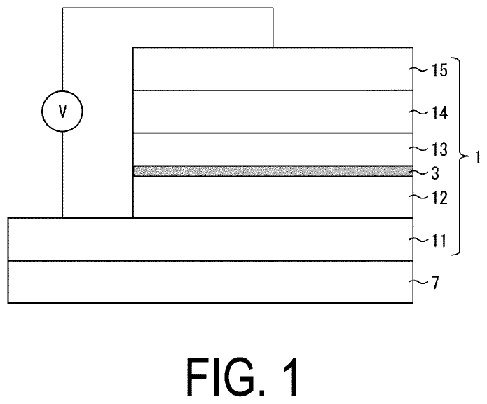

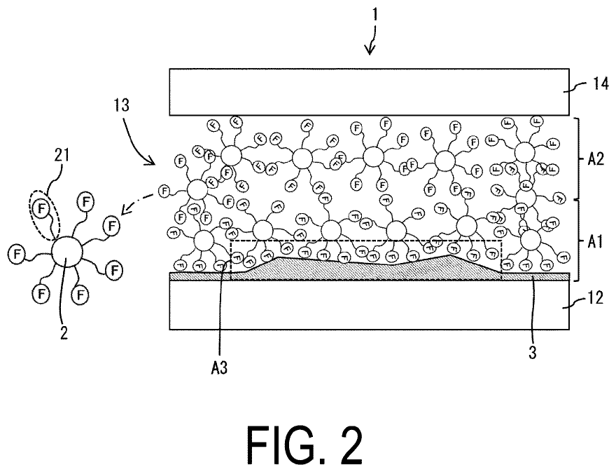

FIG. 1 is a schematic view illustrating a configuration of a light-emitting element according to a first embodiment. FIG. 2 is a cross-sectional view illustrating a configuration example of the light-emitting element. As illustrated in FIGS. 1 and 2, the light-emitting element 1 includes: a first electrode 11 and a second electrode 15; a light-emitting layer 13 located between the first electrode 11 and the second electrode 15, the light-emitting layer 13 having quantum dots 2 and containing fluorine (F); a first function layer 12 located between the first electrode 11 and the light-emitting layer 13; a second function layer 14 located between the second electrode 15 and the light-emitting layer 13; and a fluorine-containing film 3 located between the first function layer 12 and the second function layer 14.

Layers located between the first electrode 11 and the second electrode 15 other than the light-emitting layer 13 are collectively referred to as function layers. The function layers may have carrier (electron or hole) transport properties, and the function layers may be a hole injection layer (HIL), a hole transport layer (HTL), an electron transport layer (ETL), or an electron injection layer (EIL). The first electrode 11 may be an anode, the first function layer 12 may be a hole transport layer, the second function layer 14 may be an electron transport layer, and the second electrode 15 may be a cathode. The first electrode 11 may be a cathode, the first function layer 12 may be an electron transport layer, the second function layer 14 may be a hole transport layer, and the second electrode 15 may be an anode. The light-emitting element 1 may be formed on a pixel circuit substrate 7, and in this case, the first electrode 11 may be provided at a position closer to the pixel circuit substrate 7 than the second electrode 15.

The quantum dots 2 are dots including nanoparticles with a maximum width of 100 nm or less. The quantum dots 2 may have a property (light-emitting property) in which electroluminescence is generated by applying a voltage V between the first electrode 11 and the second electrode 15. The quantum dots 2 may be a core-shell type, or a shell-less type (core-exposed type).

The shape of the quantum dots 2 is not particularly limited as long as it is within a range satisfying the maximum width, and the shape is not limited to a spherical three-dimensional shape (circular cross-sectional shape). The shape may be, for example, a polygonal cross-sectional shape, a rod-shaped three-dimensional shape, a branch-shaped three-dimensional shape, or a three-dimensional shape having unevenness on the surface, or a combination of them.

The quantum dots 2 may have at least one of a crystal of a group II-VI semiconductor such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe; a crystal of a group III-V semiconductor such as GaAs, GaP, InN, InAs, InP, or InSb; and a crystal of a group IV semiconductor such as Si or Ge.

The quantum dots 2 may have, for example, a structure (core-shell structure) in which the above-described semiconductor crystal is used as a core and the core is overcoated with a shell material having a high band gap. Furthermore, the quantum dots 2 may include a ligand adsorbed (coordinated) on the surface.

The fluorine-containing film 3 may be a liquid-repellent film containing a liquid-repellent component, or may contain a polymer compound. The fluorine-containing film 3 may be a resist film having liquid repellency and containing a polymer compound.

When of two regions obtained by bisecting a region sandwiched between the first function layer 12 and the second function layer 14 in the thickness direction, a region located on the first function layer 12 side is defined as a first region A1, and a region located on the second function layer 14 side is defined as a second region A2, the fluorine-containing film 3 may be included in the first region A1. At least a portion of the fluorine-containing film 3 may be located below the light-emitting layer 13 (between the first function layer 12 and the quantum dots 2).

In the light-emitting element 1, the light-emitting layer 13 contains fluorine, and thus, arrangement unevenness of the quantum dots 2 on the fluorine-containing film 3 is reduced even when the fluorine-containing film 3 is liquid-repellent. As a result, it is possible to increase a carrier path and to suppress variations in light emission distribution.

When the liquid-repellent fluorine-containing film 3 is provided, a protection function of the first function layer 12 at the time of upper layer formation and a barrier function (function of preventing moisture from entering from the outside of the element by the fluorine-containing film 3) after completion of the element are obtained, which can enhance reliability of the light-emitting element 1.

The fluorine-containing film 3 may have insulating properties. In this case, it is possible to improve the balance (carrier balance) between holes and electrons supplied to the light-emitting layer 13 to increase external luminous efficiency (EQE).

The fluorine-containing film 3 may have a layer shape in contact with the first function layer 12. In this way, the protection function of the first function layer 12 during the process and the barrier function after completion of the element are further enhanced. The thickness of the fluorine-containing film 3 may be smaller than the thickness of the first function layer 12. This allows the surface of the first function layer 12 to have affinity for the light-emitting layer 13 while suppressing the thickness.

The light-emitting layer 13 may contain a fluorine-terminated (having a fluorine atom F at a terminal) organic compound 21. The organic compound 21 may be an additive (for example, a ligand agent). The organic compound 21 may be coordinated to the quantum dots 2 as a ligand. In this way, the quantum dots 2 are easily dispersed in the solution to facilitate coating formation. Note that the light-emitting layer 13 contains the organic compound 21, and thus it can be regarded that the organic compound 21 functions as a ligand agent (the organic compound 21 is coordinated to the quantum dots 2).

In FIG. 2, the first region A1 may have a higher fluorine concentration than that of the second region A2. That is, the fluorine-terminated organic compound 21 and the fluorine-containing film 3 are present in the first region A1, and thus the fluorine concentration becomes high. On the other hand, in the second region A2, only the organic compound 21 is present, and thus the fluorine concentration is lower than that of the first region A1. In this way, with the configuration in which the fluorine-terminated organic compound 21 is concentrated on the fluorine-containing film 3 in the first region A1, wettability of a solution (a quantum-dot solution containing the quantum dots 2 and the organic compound 21) is improved when the light-emitting layer 13 is formed by applying the solution.

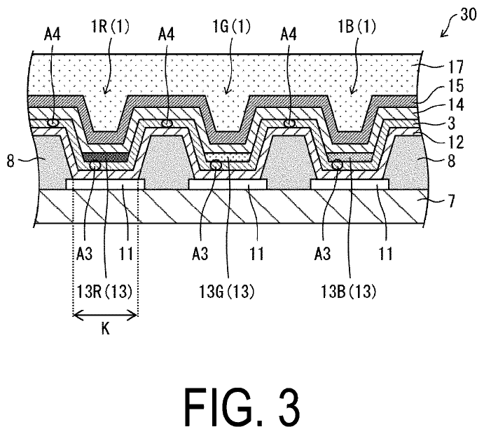

FIG. 3 is a cross-sectional view illustrating a configuration example of a display device including the light-emitting element according to the first embodiment. A display device 30 includes a plurality of light-emitting elements 1 (1R, 1G, and 1B) that emit light of different colors on the pixel circuit substrate 7. The light-emitting element 1 (1R) may include a light-emitting layer 13 (13R) that emits red light, the light-emitting element 1 (1G) may include a light-emitting layer 13 (13G) that emits green light, and the light-emitting element 1 (1B) may include a light-emitting layer 13 (13B) that emits blue light. The plurality of light-emitting elements 1 may have a common first function layer 12 and a common second function layer 14. The plurality of light-emitting elements 1 may have a common second electrode 15. A sealing layer 17 may be formed to cover the second electrode 15. The first electrode 11 may be provided at a position closer to the pixel circuit substrate 7 than the second electrode 15.

The light-emitting elements 1 in the display device 30 may each include an edge cover film 8 in contact with an end surface of the first electrode 11, and the first function layer 12 and the second function layer 14 may extend above the edge cover film 8. The edge cover film 8 may be formed over the plurality of light-emitting elements 1. When a region in which the edge cover film 8 is not present is defined as a pixel opening region K, a non-edge portion of the first electrode 11 (for example, anode) of each light-emitting element 1 may be exposed in the pixel opening region K. In the light-emitting layer 13, a portion located on the pixel opening region K emits light.

As illustrated in FIGS. 2 and 3, when a region located above the pixel opening region K and between the first function layer 12 and the quantum dots 2 is defined as a third region A3, a region located above the edge cover film 8 and between the first function layer 12 and the second function layer 14 is referred to as a fourth region A4, the third region A3 may have a higher fluorine concentration than that of the fourth region A4.

In this way, a portion of the first function layer 12 located above the pixel opening region K (portion below the third region A3) is effectively protected during and after the process (after completion of the element), and the wettability of the solution when the light-emitting layer 13 is formed by applying the solution is improved.

The third region A3 can be set to, for example, a range of a thickness D (D=0.5 nm to 20 nm) in the layering direction from the upper surface of the first function layer 12 toward the second electrode 15 above the pixel opening region K. The fourth region A4 can be set to, for example, a range of a thickness D (D=0.5 nm to 20 nm) in the layering direction from the upper surface of the first function layer 12 toward the second electrode 15 above the edge cover film 8.

The edge cover film 8 includes an insulating material (for example, a polyimide resin, an acrylic resin, a novolac resin, a fluorene resin, or the like). The edge cover film 8 can be formed by patterning a photosensitive resin material using, for example, a photolithography technique. The photosensitive resin may be negative or positive.

The fluorine-containing film 3 may be a resist film containing a polymer compound having an alkyl group, and the polymer compound may contain two or more carbon atoms. The fluorine-containing film 3 may have a thickness of 0.5 to 20 nm.

The fluorine-containing film 3 (resist film) may be formed to remain in a lump (in a continuous film shape), or may be formed in such a manner that a resist component is scattered (in an island shape). The fluorine-containing film 3 (resist film) is inserted between the light-emitting layer 13 and the first function layer 12 for one purpose of improving the carrier balance, and need not include the quantum dots 2. The fluorine-containing film 3 (resist film) may be inserted (formed) both between the first function layer 12 and the light-emitting layer 13 and between the light-emitting layer 13 and the second function layer 14.

The light-emitting layer 13 may contain a fluorine-terminated (having a fluorine atom F at a terminal) organic compound 21. The fluorine-terminated organic compound 21 may be represented by the following structural formula (1) or (2). In this case, the wettability and coatability with respect to the fluorine-containing film 3 (resist film) can be further improved.

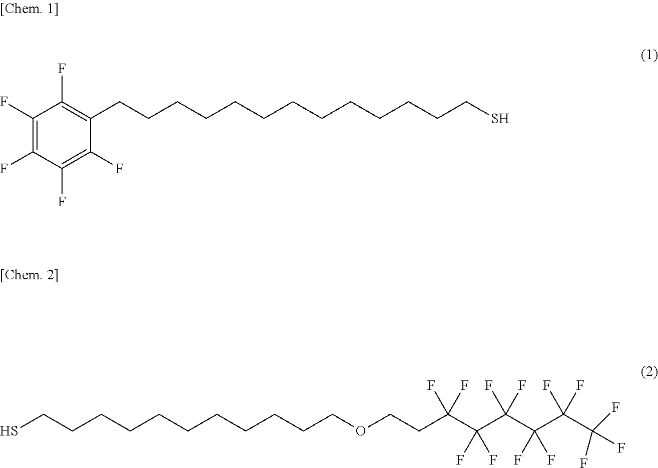 [SMILES: Fc1c(F)c(F)c(CCCCCCCCCCCCCS)c(F)c1F ; FC(F)(F)C(F)(F)C(F)(F)C(F)(F)C(F)(F)C(F)(F)CCOCCCCCCCCCCCS]

The organic compound 21 preferably contains a chain compound. This improves dispersibility of the quantum dots 2 to which the organic compound 21 is coordinated as a ligand in a non-polar solvent.

The organic compound 21 preferably has a plurality of coordinating functional groups. The coordinating functional groups include at least one of a thiol group, an amino group, a carboxyl group, and a phosphino group. This improves the dispersibility of the quantum dots 2 to which the organic compound 21 is coordinated in a polar solvent.

The organic compound 21 preferably contains a polycyclic aromatic hydrocarbon having two or more benzene rings. This improves the dispersibility of the quantum dots 2 to which the organic compound 21 (organic ligand agent) is coordinated in an aromatic compound solvent.

The organic compound 21 contained in the light-emitting element 1 can be identified by a combination of a plurality of analysis techniques including matrix assisted laser desorption/ionization-time of flight mass spectrometry (MALDI-TOF-MS), liquid chromatograph-mass spectrometry (LC-MS/MS), time-of-flight secondary ion mass spectrometry (TOF-SIMS), and the like.

A matrix-assisted laser desorption/ionization (MALDI) method is a method in which a matrix mixture is irradiated with a nitrogen laser beam (wavelength=337 nm) to rapidly (for several nanoseconds) heat a portion from the outermost surface to 100 nm to vaporize the matrix mixture.

A time-of-flight mass spectrometry (TOF-MS) method is a method of performing mass spectrometry by utilizing the fact that the time of flight of ions varies depending on a difference in mass-to-charge ratio m/z value.

A liquid chromatograph mass spectrometer (LC-MS/MS) is an apparatus in which a high performance liquid chromatograph (HPLC) and a triple quadrupole mass spectrometer (MS/MS) are combined, and in the LC-MS/MS, a mass spectrum more separated than in the LC-MS can be obtained by a connected MS part, and thus, the LC-MS/MS is excellent in identification of molecules.

In a time-of-flight secondary ion mass spectrometry (TOF-SIMS) method, when a sample is irradiated with a primary ion beam under ultra-high vacuum, secondary ions are emitted from an extreme surface (1 to 3 nm) of the sample. The secondary ions are introduced into a time-of-flight (TOF) mass spectrometer to obtain a mass spectrum of the outermost surface of the sample. At this time, a primary ion irradiation amount is reduced to a low level, whereby a surface component can be detected as molecular ions maintaining the chemical structure or a partially cleaved fragment, and information about the elemental composition or chemical structure of the outermost surface is obtained.

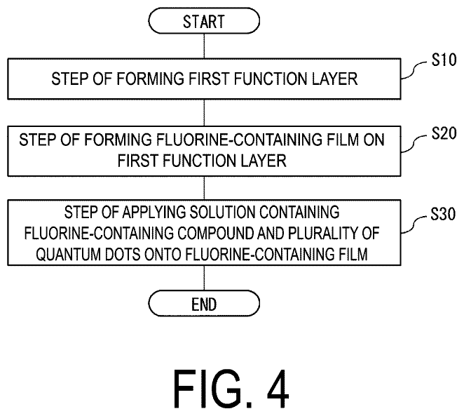

FIG. 4 is a flowchart illustrating an example of a method for manufacturing a light-emitting element according to the first embodiment. As illustrated in FIG. 4, the method for manufacturing the light-emitting element according to the first embodiment includes a step (S10) of forming the first function layer 12, a step (S20) of forming the fluorine-containing film 3 on the first function layer 12, and a step (S30) of applying a solution including the organic compound 21 containing fluorine and the quantum dots 2 onto the fluorine-containing film 3. The fluorine-containing film 3 may be a liquid-repellent resist film. The organic compound 21 may be a fluorine-terminated ligand agent.

To the quantum dots 2 used in the light-emitting layer 13, the fluorine-terminated organic compound 21 can be coordinated as a ligand by organic ligand substitution treatment. The organic ligand substitution treatment may be carried out by a general method, in which a solution containing the fluorine-terminated organic compound 21 is added to an initial quantum dot dispersion, followed by ultrasonic treatment or the like. As needed, main treatment (ultrasonic treatment, removal of supernatant, re-dispersion, or the like) is repeated.

When the fluorine-terminated organic compound 21 is coordinated to the quantum dots 2 in the solution, wettability (coatability) with respect to the fluorine-containing film 3 (for example, a liquid-repellent resist film) is improved. When the fluorine-containing film 3 is made liquid-repellent, it is possible to protect the first function layer 12 (for example, hole transport layer) during the upper layer formation (process). The polarity of the fluorine-containing film 3 may be high enough to repel water having a high polarity.

In a case where the first function layer 12 is a hole transport layer, the material of the first function layer 12 is not particularly limited as long as it is a hole transport material capable of transporting holes injected from the first electrode 11 serving as an anode to the quantum dot layer 13. For example, TFB, which is a material containing no nanoparticle, can be used.

In a case where the second function layer 14 is an electron transport layer, the material of the second function layer 14 is not particularly limited as long as it is an electron transport material capable of transporting electrons injected from the second electrode 15 serving as a cathode to the quantum dot layer 13. For example, TPBi, which is a material containing no nanoparticle, can be used.

As the material of the hole transport layer (HTL), an organic material such as poly[(9,9-dioctylfluorenyl-2,7-diyl)-co-(4,4′-(N-4-sec-butylphenyl))diphenylamine)] (TFB), poly(4-butyltriphenylamine) (p-TPD), poly(9-vinylcarbazole) (PVK), [9,9′-[1,2-phenylenebis(methylene)]bis[N3,N3,N6,N6-tetrakis(4-methoxyphenyl)-9H-carbazole-3,6-diamine] (V886), or 7,7′-bi[1,4]benzoxazino[2,3,4-kl]phenoxazine (HN-D1), or inorganic materials such as NiO nanoparticles can be used.

As the material of the electron transport layer (ETL), organic materials such as (2,2′,2″-(1,3,5-benzintriyl)-tris(1-phenyl-1-H-benzimidazole) (TPBi), bathocuproine (BCP), or nanoparticles of an organometallic complex, or an inorganic material such as nanoparticles of an n-type oxide semiconductor can be used. Examples of the organometallic complex include a tris(8-quinolinol)aluminum complex (Alq3). Examples of the n-type oxide semiconductor include metal oxides such as ZnO and ZnMgO.

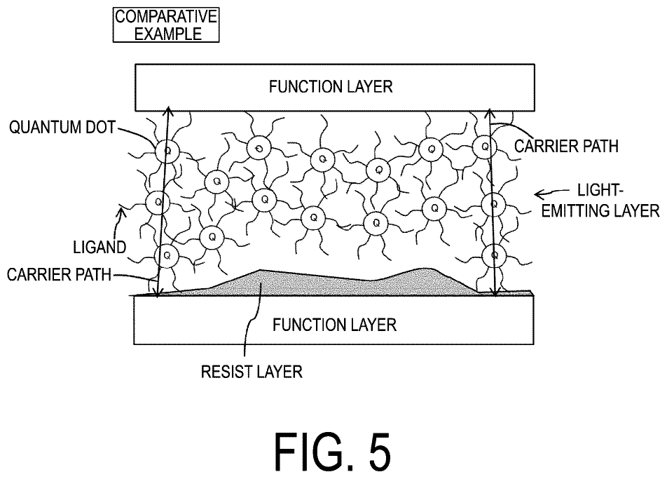

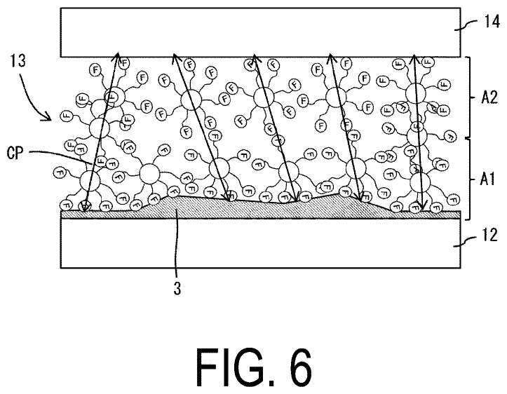

FIG. 5 is a cross-sectional view illustrating a configuration and a carrier path of a comparative example. FIG. 6 is a cross-sectional view illustrating a carrier path of the light-emitting element according to the first embodiment. In the light-emitting layer of the comparative example, a ligand of quantum dots Q on a liquid-repellent resist layer does not contain fluorine. In this case, a gap is easily formed in the light-emitting layer, which leads to an increase in interface defects between the resist layer and the light-emitting layer and deterioration in flatness of the light-emitting layer. Furthermore, as illustrated in FIG. 4, the number of carrier paths is limited by the gap formation, and thus the in-plane variation of the emission luminance is likely to occur.

In contrast, in the light-emitting element 1 according to the first embodiment, as illustrated in FIG. 6, a gap is hardly formed on the fluorine-containing film 3. This reduces the occurrence of interface defects between the fluorine-containing film 3 and the light-emitting layer 13, and improves the flatness of the light-emitting layer 13. In addition, the number of carrier paths CP increases, which makes the light emission distribution of the light-emitting layer 13 uniform, and decreases the voltage between the first electrode 11 and the second electrode 15.

An ultra-thin insulating film can be used for the fluorine-containing film 3. The ultra-thin insulating film may be made of, for example, poly(methylmethacrylate) (PMMA), polyethylenimine ethoxylated (PEIE), polyethylenimine (PEI), or the like.

### Second Embodiment

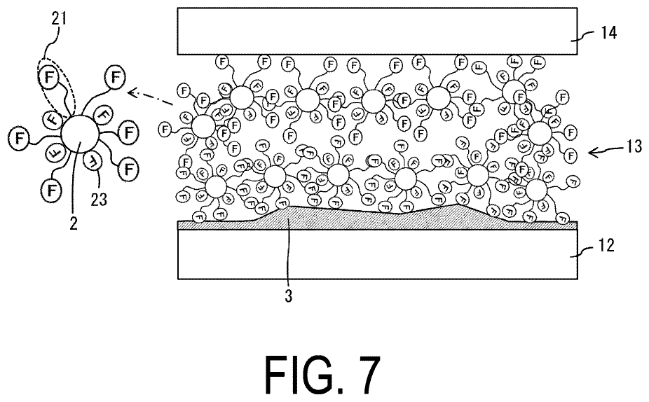

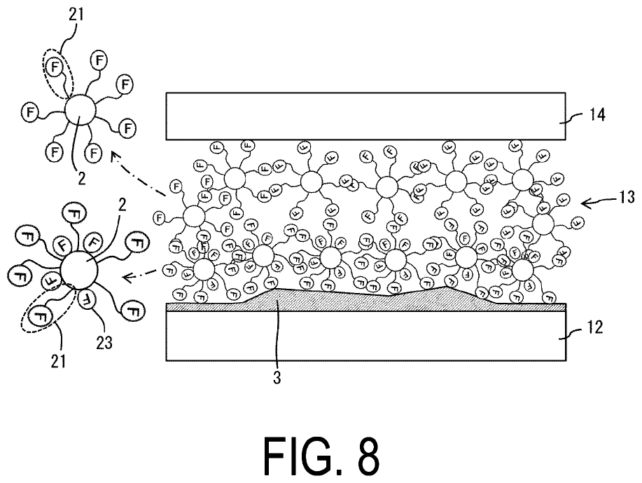

FIGS. 7 and 8 are schematic views illustrating a configuration of a light-emitting element according to a second embodiment. In the second embodiment, a fluorine-terminated organic substance 21 and a halogen atom 23 are coordinated as ligands to a quantum dot 2. The halogen atom 23 may be a fluorine atom (F) bonded to the surface of the quantum dot 2. The organic compound 21 may be a long-chain ligand and the halogen atom may be a short-chain ligand. When the short-chain ligand is bonded to the quantum dot 2 to enter a space between long-chain ligands, a gap between a fluorine-containing film 3 and the quantum dot 2 can be filled.

When the halogen atom 23 is provided as a ligand on the quantum dot 2 in addition to the organic compound 21, wettability, coatability, and reliability with respect to the fluorine-containing film 3 are further improved. Surface defects of the quantum dot 2 are compensated by the halogen atom 23, which also improves luminous efficiency. In a manufacturing method according to the second embodiment, the organic compound 21 and the halogen element only needs to be contained in the solution of FIG. 4.

In FIG. 7, in the entire light-emitting layer 13, the quantum dots 2 to which the fluorine-terminated organic compounds 21 and the halogen atoms 23 are coordinated are arranged, but the arrangement is not limited. As illustrated in FIG. 8, the quantum dots 2 to which the fluorine-terminated organic compounds 21 and the halogen atoms 23 are coordinated may be arranged in an interface portion (for example, the first layer) with the fluorine-containing film 3, and quantum dots 2 to which only the organic compounds 21 are coordinated may be arranged in the other portion. Note that when only halogen atoms are used as ligands, dispersibility of quantum dots is lowered.

### Third Embodiment

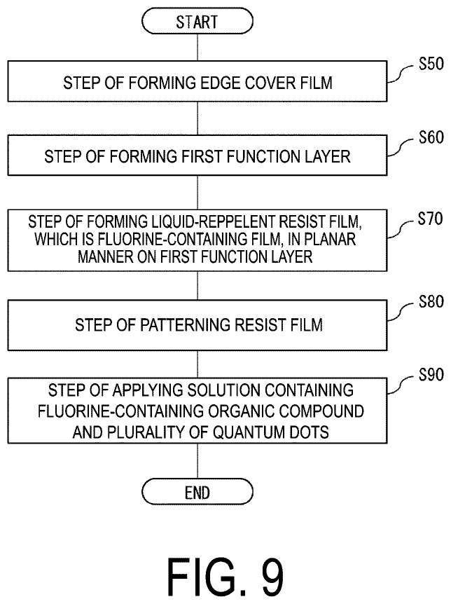

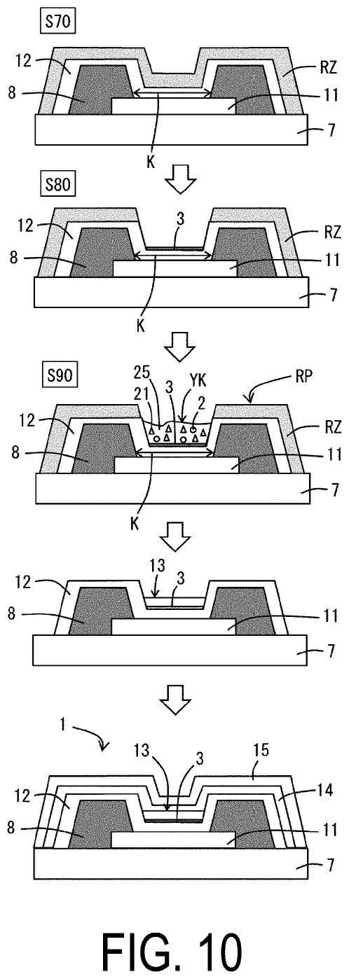

FIG. 9 is a flowchart illustrating an example of a method for manufacturing a light-emitting element according to a third embodiment. FIG. 10 is a cross-sectional view illustrating an example of the method for manufacturing the light-emitting element according to the third embodiment. In FIG. 9, a step (S50) of forming an edge cover film 8, a step (S60) of forming a first function layer 12, a step (S70, see FIG. 10) of forming a liquid-repellent resist film RZ in a planar shape on the first function layer 12, a step (S80, see FIG. 10) of patterning the planar resist film RZ, and a step (S90, see FIG. 10) of applying a solution YK containing the fluorine-containing organic compound 21 and the quantum dots 2 on the liquid-repellent resist pattern RP obtained in the step S80.

As illustrated in FIG. 10, after patterning the planar resist film RZ, the resist film (for example, island-shaped resist residual film) remaining on a region (pixel opening region K) where the edge cover film 8 is not present is the fluorine-containing film 3, and the solution YK containing the quantum dots 2, the fluorine-terminated organic compound 21 (organic ligand agent), and a solvent 25 may be applied onto the fluorine-containing film 3 which is the resist residual film. The solution YK may also be supplied over the entire surface. The fluorine-containing film 3 which is the resist residual film has lower liquid repellency than that of the resist film RZ, and thus the solution YK can be selectively applied onto the pixel opening region K. The light-emitting layer 13 can be formed by removing the solvent 25 from the solution (coating liquid) YK.

When the fluorine-terminated organic compound 21 is coordinated to the quantum dots 2 as a ligand, the solution YK can be applied even onto the liquid-repellent resist residual film (fluorine-containing film 3), and the quantum dots 2 are arranged without a large gap. In addition, when mobility of holes or electrons is adjusted by the fluorine-containing film 3 (liquid-repellent film with insulating properties) which is a resist residual film, the carrier balance can be enhanced to enhance the luminous efficiency.

The embodiments described above are for the purpose of illustration and description and are not intended to be limiting. It will be apparent to those skilled in the art that many variations will be possible in accordance with these examples and descriptions.

1. A light-emitting element, comprising:
a first electrode and a second electrode;
a light-emitting layer located between the first electrode and the second electrode, the light-emitting layer including quantum dots and including fluorine;
a first function layer located between the first electrode and the light-emitting layer;
a second function layer located between the second electrode and the light-emitting layer; and
a fluorine-containing film located between the first function layer and the second function layer.

2. The light-emitting element according to claim 1,
wherein the fluorine-containing film includes a liquid-repellent component.

3. The light-emitting element according to claim 1,
wherein the fluorine-containing film includes a polymer compound.

4. The light-emitting element according to claim 1,
wherein the fluorine-containing film has insulating properties.

5. The light-emitting element according to claim 1,
wherein when, of two regions obtained by bisecting a region sandwiched between the first function layer and the second function layer in a thickness direction, one of the two regions located on a first function layer side is defined as a first region, and the other of the two regions located on a second function layer side is defined as a second region,
the fluorine-containing film is included in the first region.

6. The light-emitting element according to claim 5,
wherein the first region has a higher fluorine concentration than a fluorine concentration of the second region.

7. The light-emitting element according to claim 1, further comprising:
an edge cover film in contact with an end surface of the first electrode,
wherein the first function layer and the second function layer extend above the edge cover film, and
when a region located between the quantum dots and the first function layer is defined as a third region, and
a region located above the edge cover film and sandwiched between the first function layer and the second function layer is defined as a fourth region,
the third region has a higher fluorine concentration than a fluorine concentration of the fourth region.

8. The light-emitting element according to claim 1,
wherein the fluorine-containing film has a layer shape in contact with the first function layer or the second function layer.

9. The light-emitting element according to claim 1,
wherein a thickness of the fluorine-containing film is smaller than a thickness of the first function layer.

10. The light-emitting element according to claim 1,
wherein the fluorine-containing film is a resist film including fluorine.

11. The light-emitting element according to claim 1,
wherein the light-emitting layer includes an organic compound including the fluorine.

12. The light-emitting element according to claim 1,
wherein the light-emitting layer includes a halogen element located on a surface of the quantum dots.

13. The light-emitting element according to claim 1,
wherein the fluorine-containing film includes a polymer compound including an alkyl group.

14. The light-emitting element according to claim 11,
wherein the organic compound is represented by Formula (1) or (2) set forth below:

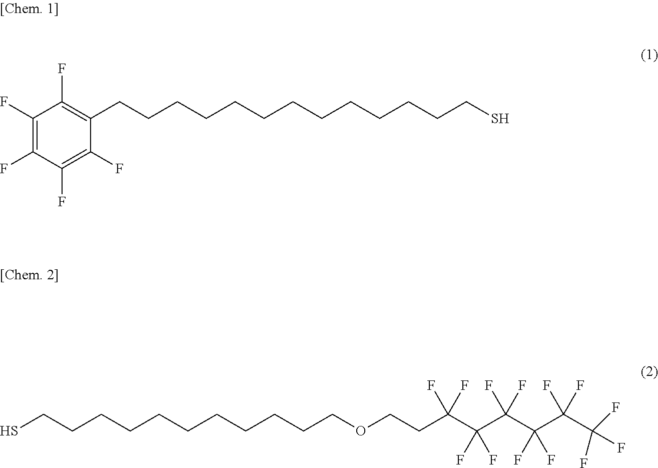 [SMILES: Fc1c(F)c(F)c(CCCCCCCCCCCCCS)c(F)c1F ; FC(F)(F)C(F)(F)C(F)(F)C(F)(F)C(F)(F)C(F)(F)CCOCCCCCCCCCCCS]

15. The light-emitting element according to claim 11,
wherein the organic compound includes a chain compound.

16. The light-emitting element according to claim 11,
wherein the organic compound includes a plurality of coordinating functional groups.

17. The light-emitting element according to claim 11,
wherein the organic compound includes a polycyclic aromatic hydrocarbon having two or more benzene rings.

18. The light-emitting element according to claim 1,
wherein the fluorine-containing film is an island-shaped resist residual film.

19. (canceled)

20. (canceled)

21. A display device, comprising:
the light-emitting element according to claim 1; and
a pixel circuit substrate,
wherein the first electrode is provided at a position closer to the pixel circuit substrate than the second electrode.

22. A method for manufacturing a light-emitting element, the method comprising:
forming a first function layer;
forming a fluorine-containing film on the first function layer; and
applying a solution including a compound including fluorine and quantum dots onto the fluorine-containing film.

23. (canceled)

24. (canceled)

25. (canceled)
